(19) United States
(12) Patent Application Publication
(10) Pub. No.: US 2003/0067047 A1
(43) Pub. Date: Apr. 10, 2003

(54) Micromechanical switch and method of manufacturing the same

(75) Inventors: Jeremy N. Sandoe, Horsham (GB); Stephen J. Battersby, Haywards Heath (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/242,121

(22) Filed: Sep. 12, 2002

(30) Foreign Application Priority Data
Oct. 4, 2001 (GB) 0123801.3

(51) Int. Cl. H01L 29/82

(52) U.S. Cl. 257/415

(57) ABSTRACT

A micromechanical switch (1) is disclosed together with a method of manufacturing the same. The micromechanical switch comprises a beam (13) at least partially suspended above a planar substrate (10); two control electrodes (12, 19), one of which is at least partially located above the beam (19) and the other is at least partially located below the beam (12), both in relation to the substrate; and at least one contact electrode (11, 18); wherein applying a potential at either one of the control electrodes generates an attractive force between that control electrode and a conductive portion of the beam (15, 17) whereby the beam is caused to deflect in a direction (25) perpendicular to the plane of the substrate; and wherein applying a potential to at least one of the control electrodes causes a conductive portion of the beam to contact the or one of the contact electrodes.

### FIELD OF INVENTION

This invention relates to a micromechanical switch and to a method of manufacturing the same.

### BACKGROUND TO INVENTION

U.S. Pat. No. 5,658,698 discloses a microstructure such as an electrostatic actuator comprising a substrate, a patterned beam member suspended over the substrate with an air-space therebetween and supporting structure for suspending the beam member over the substrate. The microstructure is prepared by using a sacrificial layer which is removed to form the space between the beam member and the substrate. Deflection of the beam is in a plane perpendicular to the substrate and in response to electrostatic attraction between the beam member (or a conductive part thereof) and a gate/control electrode located adjacent the beam as a result of applying a potential to the gate/control electrode.

In a conventional such switch, the energy stored in the cantilever capacitance varies rapidly with separation between gate/control electrodes and the cantilever. Once sufficient energy is stored, the switch closes suddenly and hysterically as the value of the separation is much smaller when the switch is closed. The “off to on” voltage therefore typically differs from the “on to off” voltage.

### OBJECTION OF INVENTION

It is an object of the invention to provide an improved micromechanical switch and a method of manufacturing the same.

### SUMMARY OF INVENTION

According to the present invention, there is provided a micromechanical switch comprising a beam at least partially suspended above a planar substrate; two control electrodes, one of which is at least partially located above the beam and the other is at least partially located below the beam, both in relation to the substrate; and at least one contact electrode; wherein applying a potential at either one of the control electrodes generates an attractive force between that control electrode and a conductive portion of the beam whereby the beam is caused to deflect in a direction perpendicular to the plane of the substrate; and wherein applying a potential to at least one of the control electrodes causes the beam to contact the or one of the contact electrodes.

If a conventional cantilever beam having a gate/control electrode underneath the beam elastically deflects and contacts a contact electrode when a potential is applied to the gate/control electrode, e.g. an “on” state, the corresponding “off” state is provided when the potential is removed and the inherent stiffness of the micromechanical switch causes the beam to return to its neutral position. This approach relies on the integrity of the beam.

With a switch according to the present invention, the beam can be more “floppy”, with the “on” and “off” states effected by applying a potential to an appropriate gate/control electrode. In this arrangement, the attractiveness of the beam to respective gate/control electrodes required to deflect the beam is less than would normally be the case as the inherent stiffness of the beam may be reduced.

For example, the beam may be sufficiently flexible as to contact either contact electrode depending on the orientation of the switch without requiring the application of a potential to either of the control electrodes. This might be achieved by forming the beam from two layers, a first layer which is flexible so as to enable the beam to deflect in a direction perpendicular to the plane of the substrate; and a second layer which serves to reinforce the beam away from the area of deflection of the first layer.

Where a switch according to the present invention comprises two contact electrodes, conveniently where one of the contact electrodes is at least partially located above the beam and the other at least partially located below the beam, both in relation to the substrate, applying a potential to one or other of the control electrodes may cause the beam to contact a corresponding contact electrode. This enables an alternative “off” state to be provided whereby the beam contacts a different electrode rather than none at all.

Also provided in accordance with the present invention is a method of manufacturing such a micromechanical switch comprising the steps of forming a first control electrode on a first planar substrate; forming a first sacrificial layer on the first control electrode; forming a beam on the first substrate; removing the first sacrificial layer to leave the beam at least partially suspended above the first control electrode; forming a second control electrode at least partially above the beam; and forming at least one contact electrode.

Forming the second control electrode above the beam may be done by forming it on a second substrate and subsequently coupling the second substrate to the first substrate.

Alternatively, forming the second control electrode above the beam may be done by forming a second sacrificial layer on the beam, forming the second control electrode on the second sacrificial layer, and subsequently removing the second sacrificial layer.

### BRIEF DESCRIPTION OF DRAWINGS

Micromechanical switches according to the present invention and methods of manufacturing the same will now be described, by way of example only, with reference to following figures in which:

FIGS. 1a and 1b are respective sections along line B-B (shown on FIG. 1b) and line A-A (shown on FIG. 1a) through a micromechanical switch according to the present invention;

FIGS. 2a and 2b, 3a and 3b, 4a and 4b and 5a and 5b are respective plan views and sections along line B-B illustrating the manufacture of the micromechanical switch of FIGS. 1a and 1b.

FIGS. 6a and 6b are respective sections along line C-C (shown on FIG. 6b) and line D-D (shown on FIG. 6a) through an alternative micromechanical switch according to the present invention;

FIGS. 7a and 7b are a respective plan view and sections along line D-D illustrating the manufacture of the micromechanical switch of FIGS. 6a and 6b; and

FIGS. 8a and 8b are respective sections along line E-E (shown on FIG. 8b) and line F-F (shown on FIG. 8a) through an alternative micromechanical switch according to the present invention.

### DETAILED DESCRIPTION

It should be noted that the above figures are not to scale. Rather, the relative dimensions and parts of these figures have either been exaggerated or reduced in size for reasons of clarity and to aid understanding of the invention. Also, the same reference signs are generally used to refer to corresponding or similar features in different embodiments.

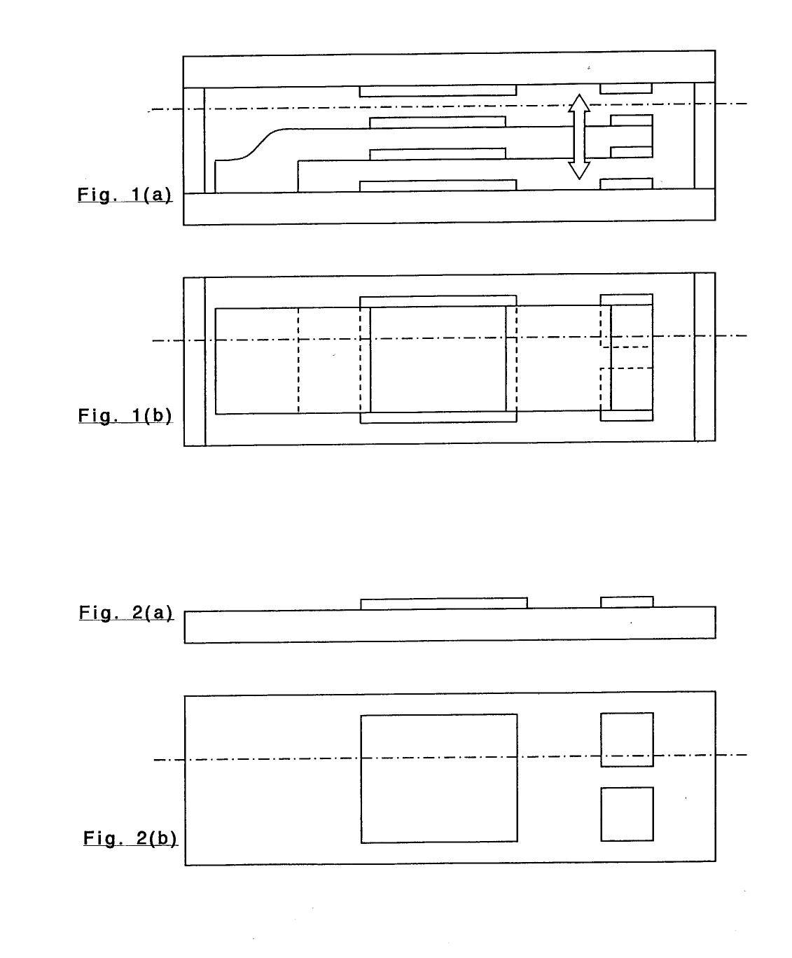

A micromechanical switch 1 according to the present invention is shown in FIGS. 1a and 1b comprising a flexible, cantilever beam 13 located between lower 10 and upper 20 substrates, and supported at one end by the lower substrate. Attached to the lower and upper substrates are two control electrodes 12, 19 and two pairs of contact electrodes 11 and 11′, 18 and 18′ respectively.

In order to deflect the beam 13, it has conductive portions 15, 17 which are electrostatically attracted to one or other of the control electrodes 12, 19 when a potential is applied thereto. When sufficient potential is applied, the beam will deflect sufficiently whereby one of two further conductive portions of the beam 14, 16 contacts the corresponding pair of contact electrodes 11 & 11′, 18 & 18′. This will establish an electrical path between the corresponding pair of contact electrodes, i.e. operation as a switch. NB. Connecting circuitry to the contact and control electrodes are omitted for clarity.

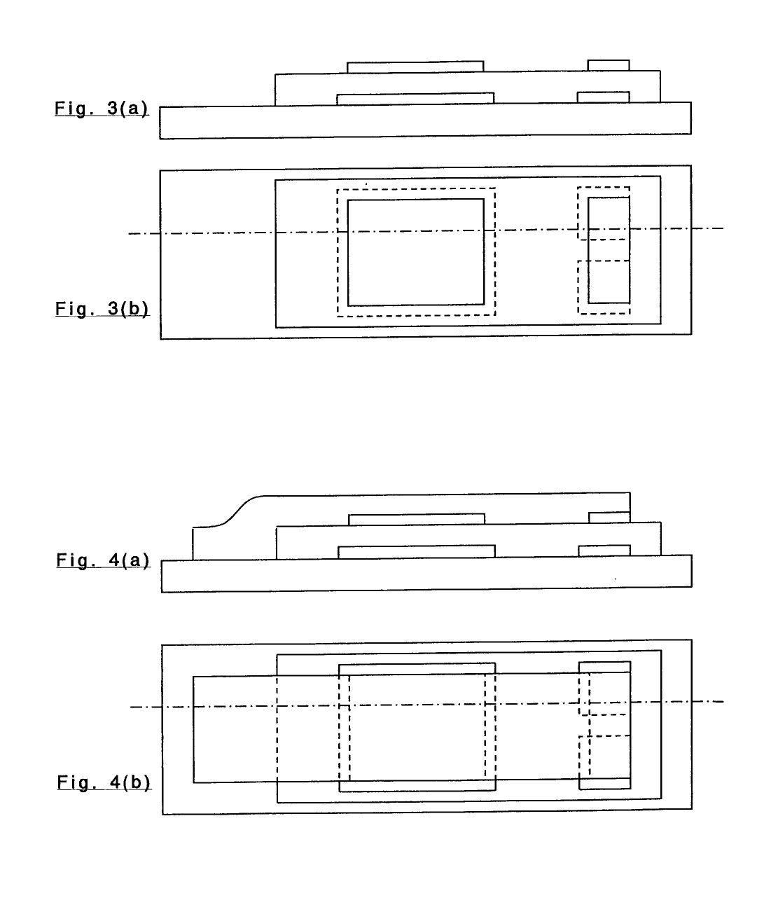

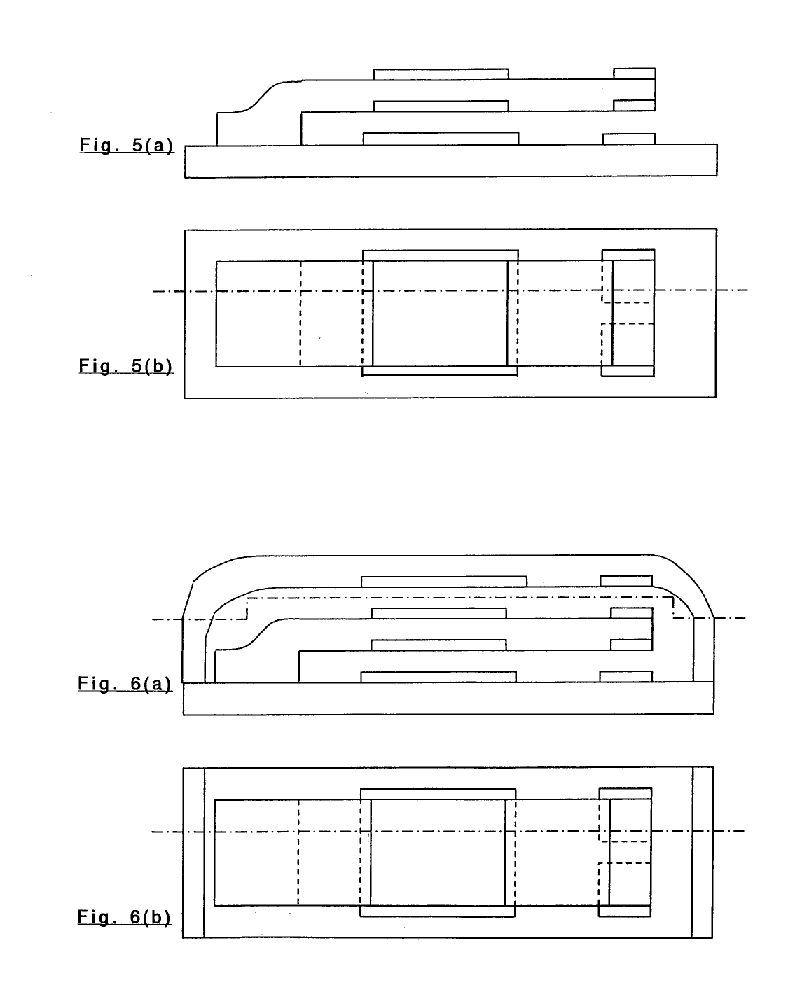

As illustrated by FIGS. 2a and 2b, 3a and 3b, 4a and 4b and 5a and 5b, such a switch may be manufactured as follows:

a conductive layer is deposited on substrate 10 and patterned to form lower control 12 and contact 11, 11′ electrodes;

a sacrificial layer 22 is deposited and patterned to cover the over the lower control 12 and contact 11, 11 electrodes;

a further conductive layer is deposited on the sacrificial layer 22 and patterned to form what will be the lower conductive portions 14, 15 of the cantilever beam 13;

the cantilever beam 13 is formed over the sacrificial layer;

a further conductive layer is deposited and patterned to form the upper conductive portions 16, 17 of the cantilever beam 13;

the sacrificial layer is removed to leave the beam partially suspending over the substrate and supporting the conductive portions; and

an upper substrate 20 with control 19 and contact 18, 18′ electrodes pre-formed thereon is coupled to the lower substrate, spaced apart by spacers 21 and with suitable alignment so that ensure the position of the control and contact electrodes correspond with the upper conductive portions of the cantilever beam.

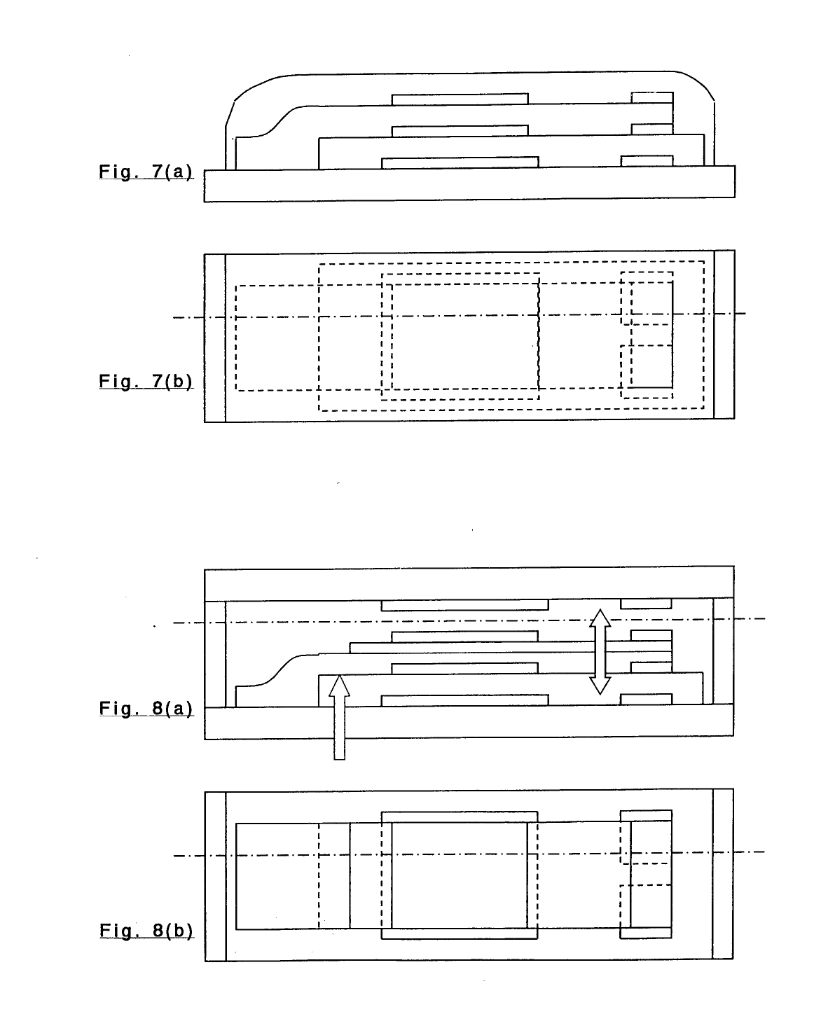

An alternative micromechanical switch according to the present invention is shown in FIGS. 6a and 6b. Instead of the planar, upper substrate 20 as present in the micromechanical switch of FIGS. 1a and 1b, the switch has a dome-shaped upper housing 23 which supports the upper control 19 and contact 18, 18′ electrodes. As illustrated in FIGS. 7a and 7b, the switch is manufactured in substantially the same way as the micromechanical switch of FIGS. 1a and 1b except that instead of coupling the upper planar substrate, a further sacrificial layer 24 is deposited and the dome-shaped housing deposited as a continuous layer and patterned thereon. Both sacrificial layers may then removed, ideally at the same time.

A further alternative micromechanical switch according to the present invention is shown in FIGS. 8a and 8b. Here, the beam is modified from that of the micromechanical switch of FIGS. 1a and 1b whereby the body of the beam 13 is flexible so as to enable deflection of the beam in the area indicated by arrow 26, and reinforced by a second layer away from that area of deflection.

Concerning suitable materials for either of the micromechanical switches described, the substrates 10, 20 would typically be insulators such as glass or plastic, or a combination of both. The beam 13 may be an organic or non-organic insulator or even a metal, the latter facilitating an alternative configuration of switch in which a conductive path from the base of the cantilever to a contact electrode is selected established (with the associated circuitry, not shown). The control and contact electrodes, and the conductive parts of an insulating beam are conveniently metal although conceivable a non-metallic conductor such as a heavily doped semiconductor material. The sacrificial layer(s) might typically be organic, photoresist type materials although again, suitable materials would suggest themselves to a person skilled in the art of micromechanical switch manufacture.

In fact, the applicant is aware of much general prior art relating to micromechanical, cantilever switches and sensors which, whilst of no direct relevance to the present invention, describes materials and manufacturing techniques equally be applicable to the present invention. For example, see the following documents incorporated herein by reference: article “Micromechanical Membrane Switches on Silicon” by K E Petersen (IBM J Res. Development, Vol. 23, No. 4, 1979); U.S. Pat. Nos. 5,818,093, 5,587,343, 5,638,946 and 5,658,698 (especially column 4, line 34 to column 5, line 50 for a discussion on sacrificial layers); PCT patent application WO96/16435 and European patent application EP0598477. Accordingly, detailed discussion of specific techniques, materials and considerations for manufacturing micromechanical switches according to the present invention, including precise process conditions, have not been unnecessarily repeated in the present disclosure.

1. A micromechanical switch comprising a beam at least partially suspended above a planar substrate; two control electrodes, one of which is at least partially located above the beam and the other is at least partially located below the beam, both in relation to the substrate; and at least one contact electrode; wherein applying a potential at either one of the control electrodes generates an attractive force between that control electrode and a conductive portion of the beam whereby the beam is caused to deflect in a direction perpendicular to the plane of the substrate; and wherein applying a potential to at least one of the control electrodes causes a conductive portion of the beam to contact the or one of the contact electrodes.

2. A switch according to claim 1 comprising two contact electrodes wherein applying a potential to one or other of the control electrodes causes a conductive portion of the beam to contact a corresponding contact electrode.

3. A switch according to claim 2 wherein one of the contact electrodes is at least partially located above the beam and the other is at least partially located below the beam, both in relation to the substrate.

4. A switch according to any of the preceding claims wherein the beam is sufficiently flexible as to contact either of the contact electrodes depending on the orientation of the switch without requiring the application of a potential to either of the control electrodes.

5. A switch according to claim 4 wherein the beam is formed from two layers, a first layer which is flexible so as to enable the beam to deflect in a direction perpendicular to the plane of the substrate; and a second layer which serves to reinforce the beam away from the area of deflection of the first layer.

6. A method of manufacturing a micromechanical switch comprising the steps of:
forming a first control electrode on a first planar substrate;
forming a first sacrificial layer on the first control electrode;
forming a beam on the first substrate;
removing the first sacrificial layer to leave the beam at least partially suspended above the first control electrode;
forming a second control electrode at least partially above the beam; and
forming at least one contact electrode,
wherein applying a potential at either one of the control electrodes of the resultant switch generates an attractive force between that control electrode and a conductive portion of the beam whereby the beam is caused to deflect in a direction perpendicular to the plane of the substrate; and wherein applying a potential to at least one of the control electrodes of the resultant switch causes a conductive portion of the beam to contact the or one of the contact electrodes.

7. A method according to claim 6 comprising two contact electrodes wherein applying a potential to one or other of the control electrodes causes a conductive portion of the beam to contact a corresponding contact electrode.

8. A method according to claim 7 wherein one of the contact electrodes is at least partially located above the beam and the other is at least partially located below the beam, both in relation to the substrate.

9. A method according to any of claims 6 to 8 wherein forming the second control electrode above the beam is done by forming it on a second substrate and subsequently coupling the second substrate to the first substrate.

10. A method according to any of claims 6 to 8 wherein forming the second control electrode above the beam is done by forming a second sacrificial layer on the beam, forming the second control electrode on the second sacrificial layer, and subsequently removing the second sacrificial layer.
